(19) United States
(12) Patent Application Publication
(10) Pub. No.: US 2024/0320388 A1
(43) Pub. Date: Sep. 26, 2024

(54) ATTRIBUTE-BASED BLOCK MODEL STORAGE

(71) Applicant: Leica Geosystems AG, Heerbrugg (CH)

(72) Inventor: Michael D. Schrag, Oro Valley, AZ (US)

(73) Assignee: Leica Geosystems AG, Heerbrugg (CH)

(21) Appl. No.: 18/188,347

(22) Filed: Mar. 22, 2023

(51) Int. Cl. G06F 30/20; G06F 3/06

(52) U.S. Cl. CPC G06F 30/20; G06F 3/0604; G06F 3/064; G06F 3/0673

(57) ABSTRACT

A method may include obtaining geological data that describes properties relating to a mineral deposit. The geological data may be represented as a plurality of attributes in which a respective attribute of the plurality includes attributes values that correspond to properties of a respective subset of the mineral deposit. The method may include defining an identification system that spatially represents the mineral deposit and assigning an attribute location value to each attribute of the plurality. The attribute location value may describe a respective location within the identification system to which the respective attribute corresponds. The method may include storing the plurality of attributes and attribute location values corresponding to the plurality of attributes using a data storage system.

The present disclosure generally relates to attribute-based block model storage.

### BACKGROUND

Geological studies may involve analysis of the physical characteristics and properties of geological rock formations. A given geological rock formation may or may not include a uniform material composition with different materials being present throughout the given geological rock formation, which may result in differing densities, shape profiles, or any other characteristics.

The subject matter claimed in the present disclosure is not limited to embodiments that solve any disadvantages or that operate only in environments such as those described above. Rather, this background is only provided to illustrate one example technology area where some embodiments described in the present disclosure may be practiced.

### SUMMARY

According to an aspect of an embodiment, a method may include obtaining geological data that describes properties relating to a mineral deposit. The geological data may be represented as a plurality of attributes in which a respective attribute of the plurality includes attributes values that correspond to properties of a respective subset of the mineral deposit. The method may include defining an identification system that spatially represents the mineral deposit and assigning an attribute location value to each attribute of the plurality. The attribute location value may describe a respective location within the identification system to which the respective attribute corresponds. The method may include storing the plurality of attributes and attribute location values corresponding to the plurality of attributes using a data storage system.

In some embodiments, defining the identification system may include specifying a three-dimensional grid and an orientation of the three-dimensional grid using a coordinate system that includes x-coordinates, y-coordinates, and z-coordinates. Assigning the attribute location value to the attribute of the plurality may include identifying a three-dimensional sub-grid in the three-dimensional grid from which the geological data corresponding to the attribute is located, the three-dimensional sub-grid representing a respective subsection of the geological data that corresponds to the respective attribute.

In some embodiments, assigning the attribute location value to the attribute of the plurality may include identifying a three-dimensional sub-grid in the three-dimensional grid from which the geological data corresponding to the attribute is located. Assigning the attribute location value to the attribute of the plurality may include determining a size of the three-dimensional sub-grid and determining a relative x-coordinate offset, a relative y-coordinate offset, and a relative z-coordinate offset between the three-dimensional sub-grid and the three-dimensional grid based on a location in the mineral deposit from which the geological data corresponding to the attribute is collected. Assigning the attribute location value to the attribute of the plurality may include determining the attribute location value based on the size of the three-dimensional sub-grid, the relative x-coordinate offset, the relative y-coordinate offset, and the relative z-coordinate offset.

In some embodiments, defining the identification system may include specifying each attribute of the plurality as a respective node to form a plurality of nodes and assigning relationships between the plurality of nodes according to an octree-based storage format in which a given parent node of the plurality of nodes includes eight respective children nodes.

In some embodiments, storing the plurality of attributes and attribute location values using the data storage system may include compressing data associated with an attribute of the plurality that includes the same attribute values and attribute location values that are within a threshold distance of one another.

In some embodiments, the properties of the mineral deposit may include physical properties that include at least one of: density, ore grade, shape, ore quantity, or material composition.

According to an aspect of an embodiment, one or more non-transitory computer-readable storage media may be configured to store instructions that, in response to being executed, cause a system to perform operations. The operations may include obtaining geological data that describes properties relating to a mineral deposit. The geological data may be represented as a plurality of attributes in which a respective attribute of the plurality includes attributes values that correspond to properties of a respective subset of the mineral deposit. The operations may include defining an identification system that spatially represents the mineral deposit and assigning an attribute location value to each attribute of the plurality. The attribute location value may describe a respective location within the identification system to which the respective attribute corresponds. The operations may include storing the plurality of attributes and attribute location values corresponding to the plurality of attributes using a data storage system.

In some embodiments, defining the identification system may include specifying a three-dimensional grid and an orientation of the three-dimensional grid using a coordinate system that includes x-coordinates, y-coordinates, and z-coordinates. Assigning the attribute location value to the attribute of the plurality may include identifying a three-dimensional sub-grid in the three-dimensional grid from which the geological data corresponding to the attribute is located, the three-dimensional sub-grid representing a respective subsection of the geological data that corresponds to the respective attribute.

In some embodiments, assigning the attribute location value to the attribute of the plurality may include identifying a three-dimensional sub-grid in the three-dimensional grid from which the geological data corresponding to the attribute is located. Assigning the attribute location value to the attribute of the plurality may include determining a size of the three-dimensional sub-grid and determining a relative x-coordinate offset, a relative y-coordinate offset, and a relative z-coordinate offset between the three-dimensional sub-grid and the three-dimensional grid based on a location in the mineral deposit from which the geological data corresponding to the attribute is collected. Assigning the attribute location value to the attribute of the plurality may include determining the attribute location value based on the size of the three-dimensional sub-grid, the relative x-coordinate offset, the relative y-coordinate offset, and the relative z-coordinate offset.

In some embodiments, defining the identification system may include specifying each attribute of the plurality as a respective node to form a plurality of nodes and assigning relationships between the plurality of nodes according to an octree-based storage format in which a given parent node of the plurality of nodes includes eight respective children nodes.

In some embodiments, storing the plurality of attributes and attribute location values using the data storage system may include compressing data associated with an attribute of the plurality that includes the same attribute values and attribute location values that are within a threshold distance of one another.

In some embodiments, the properties of the mineral deposit may include physical properties that include at least one of: density, ore grade, shape, ore quantity, or material composition.

According to an aspect of an embodiment, a system may include one or more processors and one or more non-transitory computer-readable storage media configured to store instructions that, in response to being executed, cause a system to perform operations. The operations may include obtaining geological data that describes properties relating to a mineral deposit. The geological data may be represented as a plurality of attributes in which a respective attribute of the plurality includes attributes values that correspond to properties of a respective subset of the mineral deposit. The operations may include defining an identification system that spatially represents the mineral deposit and assigning an attribute location value to each attribute of the plurality. The attribute location value may describe a respective location within the identification system to which the respective attribute corresponds. The operations may include storing the plurality of attributes and attribute location values corresponding to the plurality of attributes using a data storage system.

In some embodiments, defining the identification system may include specifying a three-dimensional grid and an orientation of the three-dimensional grid using a coordinate system that includes x-coordinates, y-coordinates, and z-coordinates. Assigning the attribute location value to the attribute of the plurality may include identifying a three-dimensional sub-grid in the three-dimensional grid from which the geological data corresponding to the attribute is located, the three-dimensional sub-grid representing a respective subsection of the geological data that corresponds to the respective attribute.

In some embodiments, assigning the attribute location value to the attribute of the plurality may include identifying a three-dimensional sub-grid in the three-dimensional grid from which the geological data corresponding to the attribute is located. Assigning the attribute location value to the attribute of the plurality may include determining a size of the three-dimensional sub-grid and determining a relative x-coordinate offset, a relative y-coordinate offset, and a relative z-coordinate offset between the three-dimensional sub-grid and the three-dimensional grid based on a location in the mineral deposit from which the geological data corresponding to the attribute is collected. Assigning the attribute location value to the attribute of the plurality may include determining the attribute location value based on the size of the three-dimensional sub-grid, the relative x-coordinate offset, the relative y-coordinate offset, and the relative z-coordinate offset.

In some embodiments, defining the identification system may include specifying each attribute of the plurality as a respective node to form a plurality of nodes and assigning relationships between the plurality of nodes according to an octree-based storage format in which a given parent node of the plurality of nodes includes eight respective children nodes.

In some embodiments, storing the plurality of attributes and attribute location values using the data storage system may include compressing data associated with an attribute of the plurality that includes the same attribute values and attribute location values that are within a threshold distance of one another.

The object and advantages of the embodiments will be realized and achieved at least by the elements, features, and combinations particularly pointed out in the claims. It is to be understood that both the foregoing general description and the following detailed description are explanatory and are not restrictive of the invention, as claimed.

### BRIEF DESCRIPTION OF THE DRAWINGS

Example embodiments will be described and explained with additional specificity and detail through the accompanying drawings in which:

FIG. 1 is a diagram of an example embodiment of a computer system configured to generate attributes representative of geological data and storage of the attributes according to at least one embodiment of the present disclosure.

FIG. 2 illustrates an example representation of data storage and compression of one or more attributes according to at least one embodiment of the present disclosure.

FIG. 3 is a flowchart of an example method of generating attributes representative of geological data and storage of the attributes according to at least one embodiment of the present disclosure.

FIG. 4 is a flowchart of an example method of assigning an attribute location value to the attributes representative of geological data according to at least one embodiment of the present disclosure.

FIG. 5 is an example computer system.

### DETAILED DESCRIPTION

Geological rock formations may be represented electronically to facilitate analysis of the geological rock formations using a computer system. Existing electronic representations of a given geological rock formation may involve modeling the given geological rock formation as a geological block model that is generated using geostatistical methods. The geological block model may be a three-dimensional grid in which each unit location of the three-dimensional grid includes data elements that represent physical attributes of the given geological rock formation at respective physical locations that correspond to the unit locations. For example, a given data element may numerically represent a material identity at a corresponding physical location of a given geological rock formation. As an additional or alternative example, the given data element may numerically represent a density or specific gravity of the corresponding physical location or an ore grade at the corresponding physical location.

Existing methods and systems of storing information relating to geological rock formations according to the geological block model may include data storage units that include attribute values corresponding to an entire model of a given geological rock formation or a subset of the model of the given geological rock formation. The data storage units may be stored in a three-dimensional table-based format in which the data storage units may be represented in different ways. For example, the data storage attributes may be retrieved as two-dimensional “slices” of data attributes, two-dimensional rows of data attributes, two-dimensional columns of data attributes, one-dimensional data attributes, or some combination thereof. Software analyzing the data storage units may iterate through the table to retrieve attribute values corresponding to the data storage units.

Storing information relating to the geological rock formations according to the geological block model may result in various data storage limitations. Updating a given geological block model by adding, removing, or modifying attribute values of the given geological block model may involve accessing all of the data attributes within blocks affected by the update, which may increase the risk of data corruption of the affected blocks of the geological block model. Additionally or alternatively, data compression of a given block may be ineffective if the attributes include dissimilar types or values. Furthermore, as the number of attributes stored in the geological block model increases, a model iteration speed may be adversely affected.

The present disclosure relates to, among other things, representing a geological block model as a collection of individual attributes rather than as blocks of attributes. Each of the attributes includes attribute values describing the blocks of the geological block model and implicitly represent a location of the attributes based on how the attributes are arranged in a data structure, which may improve the functioning of a computer running software related to the geological block model by improving how data associated with the geological block model is retrieved and modified. Because each of the attributes are represented and stored individually of each other attribute, attributes may be added, removed, or modified without affecting the storage of the other attributes. Additionally or alternatively, attribute values for adjoining blocks that include the same attribute values may be more readily compressed. New attribute types may be defined and introduced to the geological block model without affecting pre-existing attribute types. Furthermore, global attribute types and values that may apply to the entire geological block model may be more easily defined with less data storage required because such global attributes may be stored without referencing each of the pre-existing attributes included in the geological block model. Additionally or alternatively, iteration speed through the geological block model or a subset of attributes included in the geological block model may be unaffected by the total number of attributes stored in the geological block model as the iteration speed is decreased in existing geological block models.

Embodiments of the present disclosure are explained with reference to the accompanying figures.

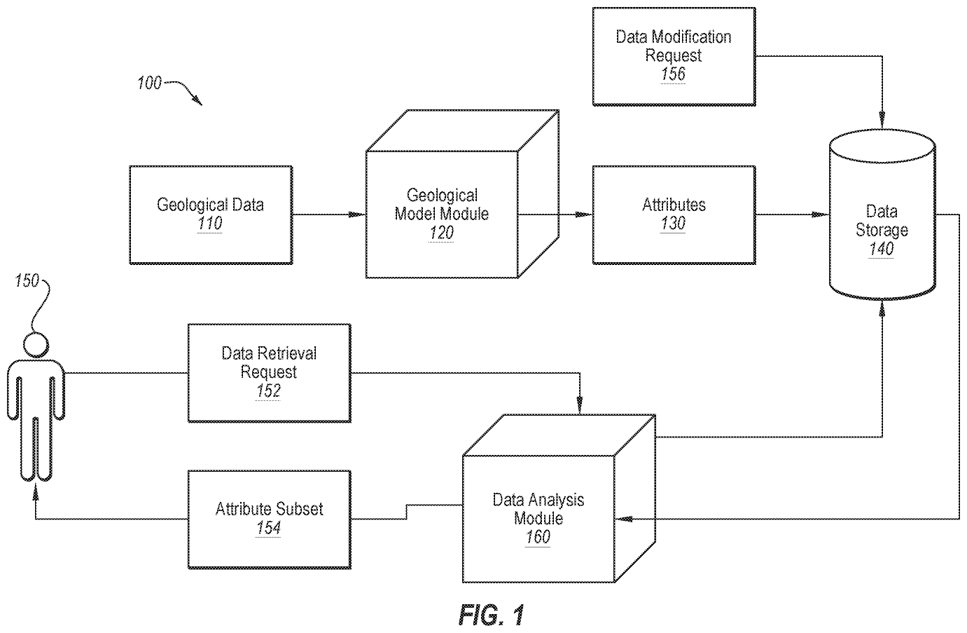

FIG. 1 is a diagram of an example embodiment of a computer system 100 configured to generate attributes representative of geological data and storage of the attributes according to at least one embodiment of the present disclosure. The system 100 may include a geological model module 120 that is configured to obtain geological data 110 relating to a mineral deposit and output attributes 130 that quantify and spatially organize properties associated with the mineral deposit. The attributes 130 may be stored in a data storage 140 to which a user 150 may make a data retrieval request 152 and be returned with a subset 154 of the attributes via a data analysis module 160.

In some embodiments, the system 100 may include the geological model module 120. The geological model module 120 may include code and routines configured to enable a computing system to perform one or more operations. Additionally or alternatively, the geological model module 120 may be implemented using hardware including a processor, a microprocessor (e.g., to perform or control performance of one or more operations), a field-programmable gate array (FPGA), or an application-specific integrated circuit (ASIC). In some other instances, the geological model module 120 may be implemented using a combination of hardware and software. In the present disclosure, operations described as being performed by the geological model module 120 may include operations that the geological model module 120 may direct one or more corresponding systems to perform. The geological model module 120 may be configured to perform a series of operations with respect to the geological data 110 and/or the attributes 130 as described in further detail below.

The geological data 110 may describe properties of the mineral deposit. In some embodiments, the geological data 110 may be collected based on preliminary drilling of the mineral deposit and/or geostatistical analysis of the mineral deposit. Information such as a density at particular locations, an ore grade, an overall shape, one or more internal shapes, an ore quantity, and/or a material composition of the mineral deposit may be measured, computed, and/or estimated in collecting the geological data 110. Additionally or alternatively, the geological data 110 may include analysis notes or other non-physical information relating to the mineral deposit. For example, the geological data 110 may include a note regarding an intended method of excavating a section of a given mineral deposit, a scheduled date for blasting a section of a given mineral deposit, a marker indicating a user intends to review geological data at a later time, or any other information that may be recorded in relation to an aspect of the mineral deposit.

The geological model module 120 may obtain the geological data 110 and output attributes 130 that quantitatively and spatially represent the geological data 110 in which the attributes 130 represent all or some of the geological data 110 corresponding to a mineral deposit of interest. In some embodiments, the geological model module 120 may be configured to represent the geological data 110 associated with each of the attributes 130 as a series of quantitative values that represent properties of interest for analysis of the mineral deposit.

The geological model module 120 may be configured to determine an attribute location value for each of the attributes 130 in which a given attribute location value is implicitly defined according to how the data associated with a correspond attribute is arranged rather than as a particular set of coordinates. In some embodiments, the geological model module 120 may be configured to specify metadata representing a three-dimensional grid that indicates overall locations and a general orientation representative of the mineral deposit. Additionally or alternatively, the geological model module 120 may capture a list of currently represented attributes 130 and types associated with one or more of the attributes 130. A given attribute 130 may represent a section of the mineral deposit and include one or more data storage units that define the attribute values corresponding to the section of the mineral deposit that the given attribute 130 represents. Included in the attribute values may be the attribute location value that provides a relative x-coordinate offset, a relative y-coordinate offset, and a relative z-coordinate offset (collectively referred to as “relative coordinate offset”) of the given attribute 130 with respect to the specified metadata defining a three-dimensional grid that is situated according to an x-, y-, z-coordinate system. For example, the attribute location value may include one or more coordinate offset values relative to a center coordinate of the mineral deposit.

In these and other embodiments, the geological model module 120 may be configured to form one or more sub-block schemas with respect to the three-dimensional grid specifying the overall locations and the general orientation representative of the mineral deposit. In some embodiments, information relating to the sub-block schemas may be recorded as attribute values in relation to one or more attributes that describe properties of the sub-block schemas, such as a size and/or a location of the sub-block schemas. The sub-block schemas may represent sub-sections of the mineral deposit and may be represented by a three-dimensional sub-grid within the three-dimensional grid specified in the metadata. In some embodiments, a variable sub-block schema may be specified based on a size of the sub-block and a set of relative coordinate offsets with respect to the three-dimensional grid specified in the metadata.

Although described in relation to a coordinate system that includes x-coordinates, y-coordinates, and z-coordinates, it may be appreciated that the geological model module 120 may be configured to use any other location-identification system. For example, each of the attributes 130 may be specified as a node and relationships between the nodes may be established according to an octree-based storage format in which a given parent node includes eight respective children nodes, and each of the children nodes may respectively include eight additional children nodes. The octree-based storage format may indicate locations of the attributes relationally to represent the relative locations of the attributes with respect to one another.

In some embodiments, the system 100 may include the data analysis module 160. The data analysis module 160 may include code and routines configured to enable a computing system to perform one or more operations. Additionally or alternatively, the data analysis module 160 may be implemented using hardware including a processor, a microprocessor (e.g., to perform or control performance of one or more operations), a field-programmable gate array (FPGA), or an application-specific integrated circuit (ASIC). In some other instances, the data analysis module 160 may be implemented using a combination of hardware and software. In the present disclosure, operations described as being performed by the data analysis module 160 may include operations that the data analysis module 160 may direct one or more corresponding systems to perform. The data analysis module 160 may be configured to perform a series of operations with respect to the data retrieval request 152 and/or the attribute subset 154 as described in further detail below.

The attributes 130 may be sent to the data storage 140, which may include a text file, a database table, or any other format for storing relational quantitative data. A user 150 may send a data retrieval request 152 to the data storage 140 via the data analysis module 160 to ask for one or more of the attributes 130 that satisfy one or more parameters, and the data analysis module 160 may be configured to retrieve an attribute subset 154 from the data storage 140 responsive to the data retrieval request 152. Because each of the attributes 130 is stored independently of one another, retrieval of the attribute subset 154 may or may not rely on iterating through all of the attributes 130 included in the data storage 140 as would be the case with existing geological block models that spatially relate the attributes in three-dimensional space.

Additionally or alternatively, a data modification request 156 may be made to the data storage 140 in which the data modification request 156 may include adding a new attribute 130 to the data storage 140, removing an existing attribute 130 from the data storage 140, modifying an attribute 130 included in the data storage 140, defining new attribute types, or any actions that may otherwise modify the attributes 130 included in the data storage 140. Because each of the attributes 130 may be stored independently of one another in the data storage 140, modification of one or more attributes 130 included in the data storage 140 according to the data modification request 156 may or may not affect other attributes 130 unrelated to the data modification request 156 that are included in the data storage 140.

Modifications, additions, or omissions may be made to the system 100 without departing from the scope of the present disclosure. For example, the designations of different elements in the manner described is meant to help explain concepts described herein and is not limiting. For instance, in some embodiments, the geological data 110, the geological model module 120, the attributes 130, the data storage 140, the data retrieval request 152, the attribute subset 154, the data modification request 156, and the data analysis module 160 are delineated in the specific manner described to help with explaining concepts described herein but such delineation is not meant to be limiting. Further, the system 100 may include any number of other elements or may be implemented within other systems or contexts than those described.

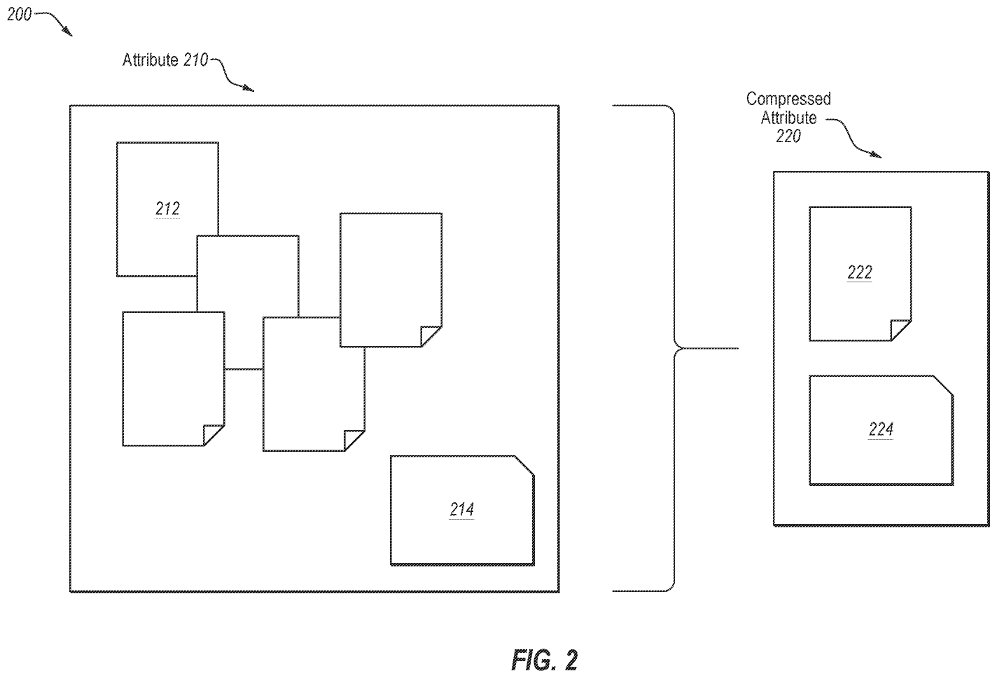

FIG. 2 illustrates an example representation 200 of data storage and compression of an attribute 210 according to at least one embodiment of the present disclosure. In some embodiments, the attribute 210 may be the same as or similar to the attributes 130 described in relation to the system 100 of FIG. 1. The attribute 210 may or may not be stored in a data storage that is the same as or similar to the data storage 140 described in relation to the system 100 of FIG. 1. The attribute 210 may include one or more attribute types that include attribute values 212 in which some of the attribute values 212 include the same value for a given attribute type. Additionally or alternatively, the attribute 210 may include attribute location values 214 in which some of the attribute location values 214 include similar values that are within a threshold distance of one another. For example, the attribute 210, the attribute types, and the attribute location values 214 may represent a uniform section of a corresponding mineral deposit, which may include the same or similar attribute values 212 at adjacent attribute location values 214 across multiple attributes.

In some embodiments, the data storage may compress the attribute 210 into a compressed attribute 220 for more efficient storage. Because the attribute 210 may include the same attribute values 212 for one or more attribute types and the same or similar attribute location values 214, the compressed attribute 220 may be more efficiently stored while sharing the same attribute values 222 and the same or similar attribute location values 224 as the attribute values 212 and the attribute location values 214, respectively.

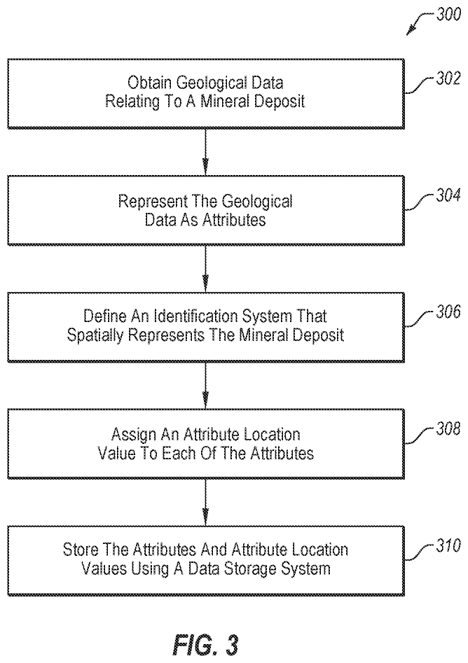

FIG. 3 is a flowchart of an example method 300 of generating attributes representative of geological data and storage of the attributes according to at least one embodiment of the present disclosure. The method 300 may be performed by any suitable system, apparatus, or device. For example, the geological model module 120 and/or the data storage 140 described in relation to the system 100 of FIG. 1 may perform one or more operations associated with the method 300. Although illustrated with discrete blocks, the steps and operations associated with one or more of the blocks of the method 300 may be divided into additional blocks, combined into fewer blocks, or eliminated, depending on the particular implementation.

The method 300 may begin at block 302, where geological data relating to a mineral deposit may be obtained. In some embodiments, the geological data may describe properties relating to the mineral deposit, such as a density at a given location, an ore grade, an overall shape, one or more internal shapes, an ore quantity, and/or a material composition of the mineral deposit.

At block 304, the geological data may be represented as individual attributes. A given attribute may include respective attribute values that correspond to properties of a respective subset of the mineral deposit.

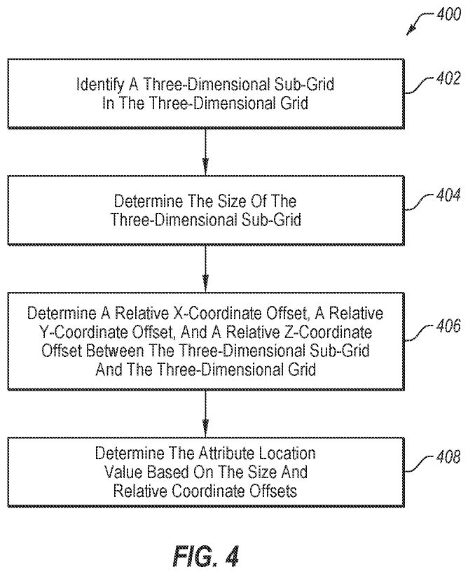

At block 306, an identification system that spatially represents the mineral deposit may be defined. In some embodiments, defining the identification system may include specifying a three-dimensional grid and an orientation of the three-dimensional grid using a coordinate system that includes x-coordinates, y-coordinates, and z-coordinates. Assigning the attribute location value to the attribute may then include identifying a three-dimensional sub-grid in the three-dimensional grid from which the geological data corresponding to the attribute is located in which the three-dimensional sub-grid represents a respective subsection of the geological data that corresponds to the respective attribute. Assigning the attribute location value to the attribute may be facilitated as described in relation to method 400 of FIG. 4 below. Additionally or alternatively, defining the identification system may include specifying each attribute as a respective node to form a set of nodes and assigning relationships between the nodes according to an octree-based storage format in which a given parent node includes eight respective children nodes and each child node respectively includes eight children nodes.

At block 308, an attribute location value may be assigned to each of the attributes. The attribute location value may describe a respective location within the three-dimensional coordinate system to which the respective attribute corresponds.

At block 310, the attributes and the attribute location values may be stored using a data storage system. In some embodiments, storing the attributes and attribute location values using the data storage system may include compressing data associated with an attribute that includes the same attribute values and attribute location values within a threshold distance of one another.

Modifications, additions, or omissions may be made to the method 300 without departing from the scope of the disclosure. For example, the designations of different elements in the manner described is meant to help explain concepts described herein and is not limiting. Further, the method 300 may include any number of other elements or may be implemented within other systems or contexts than those described.

FIG. 4 is a flowchart of an example method 400 of assigning an attribute location value to the attributes representative of geological data according to at least one embodiment of the present disclosure. The method 400 may be performed by any suitable system, apparatus, or device. For example, the geological model module 120 and/or the data storage 140 described in relation to the system 100 of FIG. 1 may perform one or more operations associated with the method 400. Although illustrated with discrete blocks, the steps and operations associated with one or more of the blocks of the method 400 may be divided into additional blocks, combined into fewer blocks, or eliminated, depending on the particular implementation.

The method 400 may begin at block 402, where a three-dimensional sub-grid may be identified within a three-dimensional grid. The three-dimensional sub-grid may represent a section of a given mineral deposit, which is itself represented by the three-dimensional grid, from which geological data corresponding to the attribute originates.

At block 404, a size of the three-dimensional sub-grid may be determined. The size of the three-dimensional sub-grid may represent a size of the section of the given mineral deposit.

At block 406, a relative x-coordinate offset, a relative y-coordinate offset, and a relative z-coordinate offset (collectively referred to as “relative coordinate offset”) between the three-dimensional sub-grid and the three-dimensional grid may be determined. The relative coordinate offset may indicate a location of the three-dimensional sub-grid, and correspondingly, the associated attribute in relation to the three-dimensional grid, and correspondingly, the mineral deposit.

At block 408, an attribute location value may be determined based on the size of the three-dimensional sub-grid and the relative coordinate offsets. The attribute location value may be stored alongside other attribute values to spatially represent the mineral deposit as a set of individual attributes with location information rather than as a spatially arranged geological block model.

Modifications, additions, or omissions may be made to the method 400 without departing from the scope of the disclosure. For example, the designations of different elements in the manner described is meant to help explain concepts described herein and is not limiting. Further, the method 400 may include any number of other elements or may be implemented within other systems or contexts than those described.

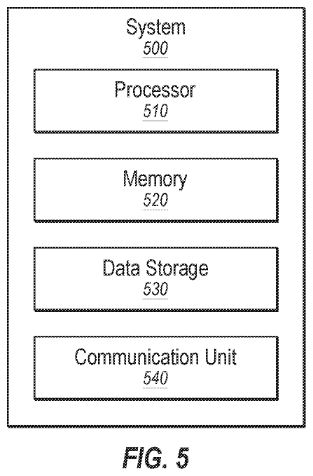

FIG. 5 is an example computing system, according to at least one embodiment described in the present disclosure. The computing system 500 may include a processor 510, a memory 520, a data storage 530, and/or a communication unit 540, which all may be communicatively coupled. Any or all of the system 100 of FIG. 1 may be implemented as a computing system consistent with the computing system 500.

Generally, the processor 510 may include any suitable special-purpose or general-purpose computer, computing entity, or processing device including various computer hardware or software modules and may be configured to execute instructions stored on any applicable computer-readable storage media. For example, the processor 510 may include a microprocessor, a microcontroller, a digital signal processor (DSP), an application-specific integrated circuit (ASIC), a Field-Programmable Gate Array (FPGA), or any other digital or analog circuitry configured to interpret and/or to execute program instructions and/or to process data.

Although illustrated as a single processor in FIG. 5, it is understood that the processor 510 may include any number of processors distributed across any number of network or physical locations that are configured to perform individually or collectively any number of operations described in the present disclosure. In some embodiments, the processor 510 may interpret and/or execute program instructions and/or process data stored in the memory 520, the data storage 530, or the memory 520 and the data storage 530. In some embodiments, the processor 510 may fetch program instructions from the data storage 530 and load the program instructions into the memory 520.

After the program instructions are loaded into the memory 520, the processor 510 may execute the program instructions, such as instructions to cause the computing system 500 to perform the operations of the method 300 of FIG. 3 or the method 400 of FIG. 4. For example, the computing system 500 may execute the program instructions to obtain geological data relating to a mineral deposit, represent the geological data as attributes, define an identification system that spatially represents the mineral deposit, assign an attribute location value to each of the attributes, store the attributes and attribute location values using a data storage system, or some combination thereof.

The memory 520 and the data storage 530 may include computer-readable storage media or one or more computer-readable storage mediums for having computer-executable instructions or data structures stored thereon. Such computer-readable storage media may be any available media that may be accessed by a general-purpose or special-purpose computer, such as the processor 510. For example, the memory 520 and/or the data storage 530 may include the geological data 110, the attributes 130, the data retrieval request 152, the attribute subset 154, and/or the data modification request 156 of FIG. 1. In some embodiments, the data storage 530 may be the same as or similar to the data storage 140 of FIG. 1. In some embodiments, the computing system 500 may or may not include either of the memory 520 and the data storage 530.

By way of example, and not limitation, such computer-readable storage media may include non-transitory computer-readable storage media including Random Access Memory (RAM), Read-Only Memory (ROM), Electrically Erasable Programmable Read-Only Memory (EEPROM), Compact Disc Read-Only Memory (CD-ROM) or other optical disk storage, magnetic disk storage or other magnetic storage devices, flash memory devices (e.g., solid state memory devices), or any other storage medium which may be used to store desired program code in the form of computer-executable instructions or data structures and which may be accessed by a general-purpose or special-purpose computer. Combinations of the above may also be included within the scope of computer-readable storage media. Computer-executable instructions may include, for example, instructions and data configured to cause the processor 510 to perform a particular operation or group of operations.

The communication unit 540 may include any component, device, system, or combination thereof that is configured to transmit or receive information over a network. In some embodiments, the communication unit 540 may communicate with other devices at other locations, the same location, or even other components within the same system. For example, the communication unit 540 may include a modem, a network card (wireless or wired), an optical communication device, an infrared communication device, a wireless communication device (such as an antenna), and/or chipset (such as a Bluetooth device, an 802.6 device (e.g., Metropolitan Area Network (MAN)), a WiFi device, a WiMax device, cellular communication facilities, or others), and/or the like. The communication unit 540 may permit data to be exchanged with a network and/or any other devices or systems described in the present disclosure. For example, the communication unit 540 may allow the system 500 to communicate with other systems, such as computing devices and/or other networks.

One skilled in the art, after reviewing this disclosure, may recognize that modifications, additions, or omissions may be made to the system 500 without departing from the scope of the present disclosure. For example, the system 500 may include more or fewer components than those explicitly illustrated and described.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, it may be recognized that changes may be made in form and detail without departing from the scope of the present disclosure. Thus, the present disclosure is limited only by the claims.

In some embodiments, the different components, modules, engines, and services described herein may be implemented as objects or processes that execute on a computing system (e.g., as separate threads). While some of the systems and processes described herein are generally described as being implemented in software (stored on and/or executed by general purpose hardware), specific hardware implementations or a combination of software and specific hardware implementations are also possible and contemplated.

Terms used in the present disclosure and especially in the appended claims (e.g., bodies of the appended claims) are generally intended as “open terms” (e.g., the term “including” should be interpreted as “including, but not limited to.”).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is expressly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase preceding two or more alternative terms, whether in the description, claims, or drawings, should be understood to contemplate the possibilities of including one of the terms, either of the terms, or both of the terms. For example, the phrase “A or B” should be understood to include the possibilities of “A” or “B” or “A and B.”

All examples and conditional language recited in the present disclosure are intended for pedagogical objects to aid the reader in understanding the present disclosure and the concepts contributed by the inventor to furthering the art, and are to be construed as being without limitation to such specifically recited examples and conditions. Although embodiments of the present disclosure have been described in detail, various changes, substitutions, and alterations could be made hereto without departing from the spirit and scope of the present disclosure.

What is claimed is:

1. A method, comprising:
obtaining geological data that describes properties relating to a mineral deposit;
representing the geological data as a plurality of attributes in which a respective attribute of the plurality includes attribute values that correspond to properties of a respective subset of the mineral deposit;
defining an identification system that spatially represents the mineral deposit;
assigning an attribute location value to each attribute of the plurality, the attribute location value describing a respective location within the identification system to which the respective attribute corresponds; and
storing the plurality of attributes and attribute location values corresponding to the plurality of attributes using a data storage system.

2. The method of claim 1, wherein defining the identification system includes specifying a three-dimensional grid and an orientation of the three-dimensional grid using a coordinate system that includes x-coordinates, y-coordinates, and z-coordinates.

3. The method of claim 2, wherein assigning the attribute location value to the attribute of the plurality includes identifying a three-dimensional sub-grid in the three-dimensional grid from which the geological data corresponding to the attribute is located, the three-dimensional sub-grid representing a respective subsection of the geological data that corresponds to the respective attribute.

4. The method of claim 2, wherein assigning the attribute location value to the attribute of the plurality includes:
identifying a three-dimensional sub-grid in the three-dimensional grid from which the geological data corresponding to the attribute is located; and
determining a size of the three-dimensional sub-grid;
determining a relative x-coordinate offset, a relative y-coordinate offset, and a relative z-coordinate offset between the three-dimensional sub-grid and the three-dimensional grid based on a location in the mineral deposit from which the geological data corresponding to the attribute is collected; and
determining the attribute location value based on the size of the three-dimensional sub-grid, the relative x-coordinate offset, the relative y-coordinate offset, and the relative z-coordinate offset.

5. The method of claim 1, wherein defining the identification system includes specifying each attribute of the plurality as a respective node to form a plurality of nodes and assigning relationships between the plurality of nodes according to an octree-based storage format in which a given parent node of the plurality of nodes includes eight respective children nodes.

6. The method of claim 1, wherein storing the plurality of attributes and attribute location values using the data storage system includes compressing data associated with an attribute of the plurality that includes the same attribute values and attribute location values that are within a threshold distance of one another.

7. The method of claim 1, wherein the properties of the mineral deposit include physical properties that include at least one of: density, ore grade, shape, ore quantity, or material composition.

8. One or more non-transitory computer-readable storage media configured to store instructions that, in response to being executed, cause a system to perform operations, the operations comprising:
obtaining geological data that describes properties relating to a mineral deposit;
representing the geological data as a plurality of attributes in which a respective attribute of the plurality includes attribute values that correspond to properties of a respective subset of the mineral deposit;
defining an identification system that spatially represents the mineral deposit;
assigning an attribute location value to each attribute of the plurality, the attribute location value describing a respective location within the identification system to which the respective attribute corresponds; and
storing the plurality of attributes and attribute location values corresponding to the plurality of attributes using a data storage system.

9. The one or more non-transitory computer-readable storage media of claim 8, wherein defining the identification system includes specifying a three-dimensional grid and an orientation of the three-dimensional grid using a coordinate system that includes x-coordinates, y-coordinates, and z-coordinates.

10. The one or more non-transitory computer-readable storage media of claim 9, wherein assigning the attribute location value to the attribute of the plurality includes identifying a three-dimensional sub-grid in the three-dimensional grid from which the geological data corresponding to the attribute is located, the three-dimensional sub-grid representing a respective subsection of the geological data that corresponds to the respective attribute.

11. The one or more non-transitory computer-readable storage media of claim 9, wherein assigning the attribute location value to the attribute of the plurality includes:
identifying a three-dimensional sub-grid in the three-dimensional grid from which the geological data corresponding to the attribute is located; and
determining a size of the three-dimensional sub-grid;
determining a relative x-coordinate offset, a relative y-coordinate offset, and a relative z-coordinate offset between the three-dimensional sub-grid and the three-dimensional grid based on a location in the mineral deposit from which the geological data corresponding to the attribute is collected; and
determining the attribute location value based on the size of the three-dimensional sub-grid, the relative x-coordinate offset, the relative y-coordinate offset, and the relative z-coordinate offset.

12. The one or more non-transitory computer-readable storage media of claim 8, wherein defining the identification system includes specifying each attribute of the plurality as a respective node to form a plurality of nodes and assigning relationships between the plurality of nodes according to an octree-based storage format in which a given parent node of the plurality of nodes includes eight respective children nodes.

13. The one or more non-transitory computer-readable storage media of claim 8, wherein storing the plurality of attributes and attribute location values using the data storage system includes compressing data associated with an attribute of the plurality that includes the same attribute values and attribute location values that are within a threshold distance of one another.

14. The one or more non-transitory computer-readable storage media of claim 8, wherein the properties of the mineral deposit include physical properties that include at least one of: density, ore grade, shape, ore quantity, or material composition.

15. A system, comprising:
one or more processors; and
one or more non-transitory computer-readable storage media configured to store instructions that, in response to being executed, cause a system to perform operations, the operations comprising:
obtaining geological data that describes properties relating to a mineral deposit;
representing the geological data as a plurality of attributes in which a respective attribute of the plurality includes attribute values that correspond to properties of a respective subset of the mineral deposit;
defining an identification system that spatially represents the mineral deposit;
assigning an attribute location value to each attribute of the plurality, the attribute location value describing a respective location within the identification system to which the respective attribute corresponds; and
storing the plurality of attributes and attribute location values corresponding to the plurality of attributes using a data storage system.

16. The system of claim 15, wherein defining the identification system includes specifying a three-dimensional grid and an orientation of the three-dimensional grid using a coordinate system that includes x-coordinates, y-coordinates, and z-coordinates.

17. The system of claim 16, wherein assigning the attribute location value to the attribute of the plurality includes identifying a three-dimensional sub-grid in the three-dimensional grid from which the geological data corresponding to the attribute is located, the three-dimensional sub-grid representing a respective subsection of the geological data that corresponds to the respective attribute.

18. The system of claim 16, wherein assigning the attribute location value to the attribute of the plurality includes:
identifying a three-dimensional sub-grid in the three-dimensional grid from which the geological data corresponding to the attribute is located; and
determining a size of the three-dimensional sub-grid;
determining a relative x-coordinate offset, a relative y-coordinate offset, and a relative z-coordinate offset between the three-dimensional sub-grid and the three-dimensional grid based on a location in the mineral deposit from which the geological data corresponding to the attribute is collected; and
determining the attribute location value based on the size of the three-dimensional sub-grid, the relative x-coordinate offset, the relative y-coordinate offset, and the relative z-coordinate offset.

19. The system of claim 15, wherein defining the identification system includes specifying each attribute of the plurality as a respective node to form a plurality of nodes and assigning relationships between the plurality of nodes according to an octree-based storage format in which a given parent node of the plurality of nodes includes eight respective children nodes.

20. The system of claim 15, wherein storing the plurality of attributes and attribute location values using the data storage system includes compressing data associated with an attribute of the plurality that includes the same attribute values and attribute location values that are within a threshold distance of one another.
